(19) United States
(12) Patent Application Publication
(10) Pub. No.: US 2020/0286970 A1
(43) Pub. Date: Sep. 10, 2020

(54) OLED DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Wenjing YU, Wuhan (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/475,871

(22) PCT Filed: Oct. 10, 2018
(86) PCT No.: PCT/CN2018/109742

§ 371 Date: Jul. 3, 2019

(30) Foreign Application Priority Data
Aug. 3, 2018 (CN) 201810874670.4

(51) Int. Cl. H01L 27/32; H01L 51/56; H01L 51/52

(52) U.S. Cl. CPC H01L 27/3246; H01L 51/56; H01L 27/3262; H01L 27/322; H01L 51/5237; H01L 51/5284

(57) ABSTRACT

An organic light diode (OLED) display panel and a manufacturing method thereof are provided. The OLED display panel includes a thin film transistor layer, a pixel defining layer, and spacers formed on a substrate. Pixel units formed in pixel regions are defined by the pixel defining layer. A thin film encapsulation layer and a color film layer are formed on the pixel units. The color film layer includes color filter layers corresponding to the pixel units, and a light shielding layer disposed at each of intervals between the color filter layers. Material of the spacers is light shielding material.

### FIELD OF INVENTION

The present application relates to a technical field of display panels, and in particular, to an organic light emitting diode (OLED) display panel and a manufacturing method thereof.

### BACKGROUND OF DISCLOSURE

Currently, polarizer-less (POL-less) structures are often used to replace polarizers to increase contrast of a display. In POL-less technology, color filters corresponding to the colors of R, G, and B pixels of an organic light emitting diode (OLED) are placed above the R, G, and B pixels, so that light emitted by the OLED is transmitted through the color filters to outside, and only the color lights of external sunlight corresponding to the colors of the color filters is allowed to pass through the color filters.

In order to improve the contrast of the display, a low temperature black matrix is disposed between the color filters, so that the sunlight in the non light-emitting region may also be absorbed, but this method has limitations: First, due to manufacturing issues, an optical density (OD) value of the low temperature black matrix is not high enough to completely absorb the external sunlight. The unabsorbed sunlight may pass out again due to reflection and refraction. Moreover, the external light entering the display via the color filters may pass out again through the low temperature black matrix or the adjacent color filters due to the reflection of a blank area (pixel definition layer). Therefore, the contrast of the display cannot meet the needs of consumers.

Therefore, it is necessary to provide an OLED display panel to solve the problems of prior art.

### SUMMARY OF INVENTION

The present disclosure provides an organic light emitting diode (OLED) display panel and a manufacturing method thereof, which solve the problem that the black matrix in the color film layer cannot completely absorb the external sunlight, and the external light transmitted through the color filter layers passes out again due to the reflection, thereby causing the low contrast of the display.

To achieve the above objective, the technical solution provided by the present disclosure is as follows:

The present disclosure provides an organic light-emitting diode (OLED) display panel, comprising:

a substrate;

a thin film transistor layer formed on the substrate;

a pixel defining layer formed on the thin film transistor layer, and defining pixel regions;

a plurality of spacers formed on the pixel defining layer;

a plurality of pixel units formed in the pixel regions and arranged in an array;

a thin film encapsulation layer formed on the pixel units; and

a color film layer formed on the film encapsulation layer, wherein the color film layer includes: a plurality of color filter layers, each of which corresponds to one of the pixel units, and a light shielding layer disposed at each of intervals between the color filter layers, and extending to edges of the color filter layers.

In the OLED display panel of the present disclosure, material of the spacers is light shielding material, and the spacers extend toward the pixel regions.

In the OLED display panel of the present disclosure, the light shielding layer is a black matrix.

In the OLED display panel of the present disclosure, the plurality of spacers are disposed around at least one of the pixel regions and extend toward the adjacent pixel regions to edges of the pixel regions.

In the OLED display panel of the present disclosure, a surface of the pixel defining layer is provided with recesses, and each of the recesses extends from an edge of one of the pixel regions to an edge of an adjacent one of the pixel regions, wherein each of the spacers is formed within one of the recesses.

In the OLED display panel of the present disclosure, material of the light shielding layer is same as the material of the spacers.

In the OLED display panel of the present disclosure, at least a portion of a side of the pixel defining layer away from the thin film transistor layer is made of light shielding material.

To achieve the above objective, the present disclosure provides a manufacturing method for an organic light-emitting diode (OLED) display panel, comprising steps of:

Step S10 of providing a substrate, and forming a thin film transistor layer and a pixel defining layer on the substrate, wherein the pixel defining layer defines pixel regions distributed in an array;

Step S20 of forming spacers on the pixel defining layer, and then forming pixel units in the pixel regions; and

Step S30 of forming a thin film encapsulation layer on the pixel units, and then forming a color film layer on the thin film encapsulation layer, wherein the color film layer includes: a plurality of color filter layers, each of which corresponds to one of the pixel units, and a light shielding layer disposed at each of intervals between the color filter layers;

wherein material of the spacers is light shielding material, and the spacers extend toward the pixel regions.

In the manufacturing method for the present disclosure, the plurality of spacers are disposed around at least one of the pixel regions and extend toward the adjacent pixel regions to edges of the pixel regions.

In the manufacturing method for the present disclosure, the step S30 of forming the color film layer on the thin film encapsulation layer includes:

Step S301 of firstly forming a light shielding film on the thin film encapsulation layer, and patterning the light shielding film to form the light shielding layer corresponding to each of the intervals between any two of the adjacent pixel units; and

Step S302 of forming the color filter layers on the thin film encapsulation layer at positions corresponding to the pixel units.

In the manufacturing method for the present disclosure, the step S30 of forming the color film layer on the thin film encapsulation layer includes:

Step S301 of firstly forming color filter films on the film encapsulation layer, and patterning the color filter films to form the color filter layers, each of which corresponds to one of the pixel units; and

Step S302 of forming a light shielding film on the color filter layers, and patterning the light shielding film to form the light shielding layer at each of the intervals between any two of the adjacent color filter layers, wherein the light shielding layer extends to edges of the color filter layers.

To achieve the above objective, the present disclosure provides an organic light-emitting diode (OLED) display panel, comprising:

a substrate;

a thin film transistor layer formed on the substrate;

a pixel defining layer formed on the thin film transistor layer, and defining pixel regions;

a plurality of spacers formed on the pixel defining layer;

a plurality of pixel units formed in one of the pixel regions and arranged in an array;

a thin film encapsulation layer formed on the pixel units; and

a color film layer formed on the film encapsulation layer, wherein the color film layer includes: a plurality of color filter layers, each of which corresponds to one of the pixel units, and a light shielding layer disposed at each of intervals between the color filter layers;

In the OLED display panel of the present disclosure, material of the spacers is light shielding material, and each of the spacers extend toward the adjacent pixel regions.

In the OLED display panel of the present disclosure, the light shielding layer is a black matrix.

In the OLED display panel of the present disclosure, the plurality of spacers are disposed around at least one of the pixel regions and extend toward the adjacent pixel regions to edges of the pixel regions.

In the OLED display panel of the present disclosure, a surface of the pixel defining layer is provided with recesses, and each of the recesses extends from an edge of one of the pixel regions toward an edge of an adjacent one of the pixel regions, wherein each of the spacers is formed within one of the recesses.

In the OLED display panel of the present disclosure, material of the light shielding layer is same as the material of the spacers.

In the OLED display panel of the present disclosure, at least a portion of a side of the pixel defining layer away from the thin film transistor layer is made of light shielding material.

The beneficial effects of the present disclosure are as follows: In the OLED display panel and the manufacturing method thereof provided by the present disclosure, by arranging the color filter layers corresponding to the colors of the pixel units above the pixel units, and by locating a light shielding layer at each of intervals between the color filter layers, the manufacturing process orders of the color filter layers and the light shielding layer is used to improve the contrast of the display panel. In addition, by changing material of the spacers disposed on the pixel defining layer between the adjacent subpixels into a black light-absorbing material, the spacers are used for both support and light shielding for further improving the contrast of the display panel. Since when irradiating the corresponding pixel defining layer, the external light, which is not absorbed by the light shielding layer or transmits through the color filter layers, is reabsorbed by the spacers, thereby preventing the external light entering the display from passing out again due to reflection or refraction, and thereby increasing the contrast of the display.

### BRIEF DESCRIPTION OF DRAWINGS

In order to more clearly illustrate the embodiments of the present invention or the technical solutions in prior arts, the following briefly introduces the accompanying drawings used in the embodiments. Obviously, the drawings in the following description merely show some of the embodiments of the present invention. As regards one of ordinary skill in the art, other drawings can be obtained in accordance with these accompanying drawings without making creative efforts.

FIG. 1A-FIG. 1B are partial schematic diagrams of an organic light emitting diode (OLED) display panel in prior art.

FIG. 2 is a partial cross-sectional diagram of an OLED display panel according to an embodiment of the present disclosure.

FIG. 3 is a structural schematic diagram of an OLED display panel according to an embodiment of the present disclosure.

FIG. 4 is a flowchart of a method for manufacturing an OLED display panel according to an embodiment of the present disclosure.

### DETAILED DESCRIPTION OF PREFERRED EMBODIMENTS

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side surface”, etc. are only directions with regard to the accompanying drawings. Therefore, the directional terms used for describing and illustrating the present disclosure are not intended to limit the present disclosure.

The present disclosure aims at the technical problem in the organic light emitting diode (OLED) display panel in the prior art that that the black matrix in the color film layer cannot completely absorb the external sunlight, and the external light transmitted through the color filter layers passes out again due to the reflection, thereby causing the low contrast of the display. The embodiment of the present disclosure may solve the defects.

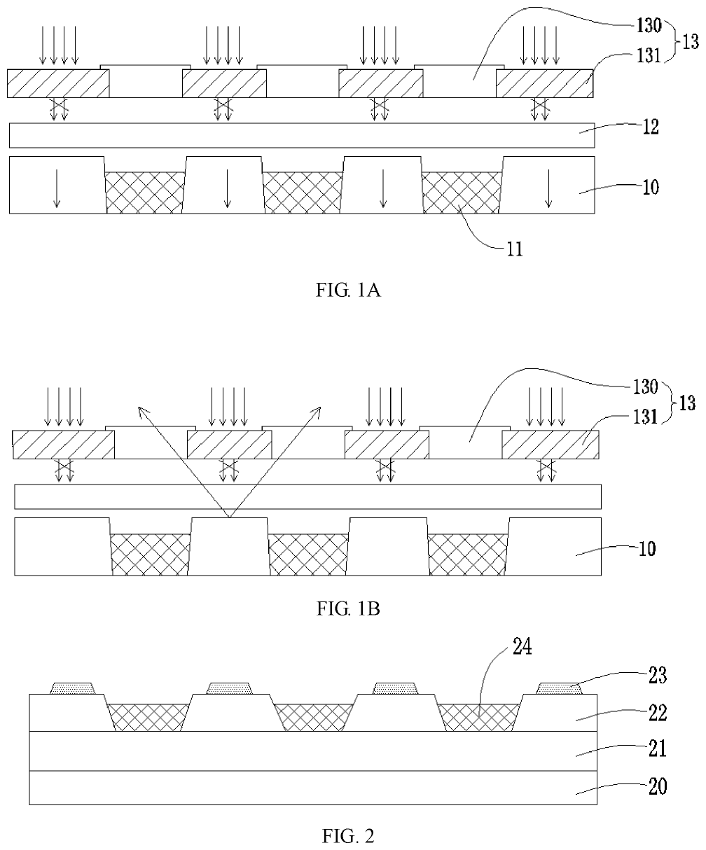

Please refer to FIG. 1A-FIG. 1B, which are partial schematic diagrams of an OLED display panel in prior art. The OLED display panel includes a pixel defining layer 10, a light emitting layer 11, a thin film encapsulation layer 12, and a color film layer 13, which are sequentially formed on a substrate. The light emitting layer 11 includes red subpixels 110, green subpixels 111, and blue subpixels 112. The color film layer 13 includes a plurality of color filter layers 130 corresponding to the subpixels, and a black matrix 131 disposed at each of intervals between the color filter layers 130. However, the black matrix 131 may not have a high enough optical density (OD) value due to manufacturing issues, so that the sunlight irradiating the non light-emitting area of the display panel (ie, the black matrix 131) cannot be completely absorbed by the black matrix 131, as shown by arrows in FIG. 1A, a part of the sunlight transmitted through the black matrix 131 may pass out again due to reflection and refraction, thereby causing low contrast of the display.

As shown in FIG. 1A, the external light, which is not absorbed by the black matrix 131, affects the contrast of the display panel by the refraction of the pixel defining layer 10. Because only the color light of external light corresponding to the colors of the color filters is allowed to pass through the color filters 130, as shown in FIG. 1B, the external light entering the display via the color filter layers 130 may pass out again through the black matrix 131 or the adjacent color filter layers 130 due to the reflection of the pixel definition layer 130, thereby causing low contrast of the display. Therefore, further improvements are needed for this type of display panel.

FIG. 2 is a partial cross-sectional diagram of an OLED display panel according to an embodiment of the present disclosure. The OLED display panel includes a substrate 20, a thin film transistor layer 21 formed on the substrate 20, a pixel defining layer 22 formed on the thin film transistor layer 21 and defining pixel regions, a plurality of spacers 23 surrounding at least one of pixel regions and formed on the pixel defining layer, a plurality of pixel units 24 formed in the pixel regions and arranged in an array, a thin film encapsulation layer (not shown in figures) formed on the pixel units 24 and the pixel defining layer 22; and a color film layer (not shown in figures) formed on the film encapsulation layer. Material of the spacers 23 is light shielding material, and each of the spacers 23 extends toward the adjacent pixel regions. Preferably, material of the spacers 23 is black light shielding material.

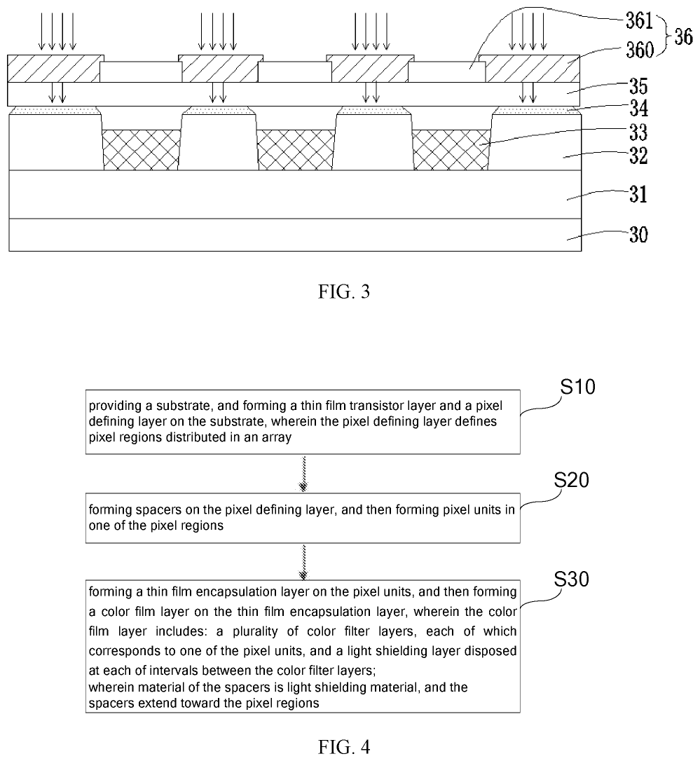

FIG. 3 is a structural schematic diagram of an OLED display panel according to an embodiment of the present disclosure. The OLED display panel includes a substrate 30, a thin film transistor layer 31 formed on the substrate 30, and a pixel defining layer 32 formed on the thin film transistor layer 31 and defining pixel regions. Pixel units 33 are formed in the pixel regions between two adjacent pixel defining layers 32. Each of the pixel units 33 includes an anode layer, a light emitting layer and a cathode layer. Spacers 34 are formed on the pixel defining layer 32 as support in deposition of the light emitting layer. A thin film encapsulation layer 35 is formed on the pixel units 33 and the spacers 34, and a color film layer 36 is formed on the thin film encapsulation layer 35. The color film layer 36 includes a plurality of color filter layers 361 corresponding to the pixel units 33, and a light shielding layer 360 disposed at each of the intervals between the color filter layers 361. The color filter layers 361 with colors corresponding to subpixels are disposed above the subpixels.

Please refer to FIG. 3, the light shielding layer 360 could be a low temperature black matrix. Two manufacturing schemes are proposed in the embodiment regarding the color film layer 36. First, the light shielding layer 360 is formed, and then the color filter layers 361 are formed. In this scheme, the color filter layers 361 may be deposited by ink jet printing (IJP) technology. The use of photoresists is not required for UP technology, thereby reducing damage to the OLED structure in the manufacturing process. Secondly, the color filter layers 361 are first formed, and then the light shielding layer 360 is formed. This scheme causes the light shielding layer 360 to extend to the edges of the color filter layers 361, thereby enhancing the light absorbing effect of the light shielding layer 360 and further improving the contrast of the display panel.

In addition, in order to further improve the contrast of the display panel, material of the spacers 34 is replaced by dark material, thereby improving the contrast of the display panel. Preferably, material of the spacers 34 is black organic material, which may absorb the external light that is not absorbed by the light shielding layer 360.

Preferably, the spacers 34 extend toward the adjacent pixel regions to the edges of the pixel regions.

When the external light irradiates a surface of the display panel, most of the external light is absorbed by the light shielding layer 360 due to the light shielding effect of the light shielding layer 360 of the color film layer 36. However, due to factors in the manufacturing process of the light shielding layer 360, an OD value of the light shielding layer 360 is not high enough, and, hence, a part of the external light irradiates the position corresponding to the pixel defining layer 32 through the light shielding layer 360. Nevertheless, because the spacers 34 are formed on a surface of the pixel defining layer 32, the external light which is not absorbed by the light shielding layer 360 is reabsorbed by the spacers 34, thereby preventing the external light entering the display from passing out again due to reflection or refraction. In addition, when the external light enters the display panel through the color filter layer 361, the spacers 34 may absorb the external light irradiating the pixel defining layer 32 and prevent the external light from being reflected by the pixel defining layer 32 to pass out through the color filter layers 361 and the light shielding layer 360.

In addition, a surface of the pixel defining layer 32 is provided with recesses, and each of the recesses extends from an edge of one of the pixel regions to an edge of an adjacent one of the pixel regions, wherein each of the spacers 34 is formed within one of the recesses. That is, the pixel defining layer 32 may be partially removed, and light shielding material that is identical or similar to material of the spacers 34 is filled in a removed portion, thereby increasing an area of the spacers 34, and improving the contrast of the display panel. Alternatively, at least a portion of a side of the pixel defining layer 32 away from the thin film transistor layer 31 is made of light shielding material. There is a certain distance between the spacers 34 and the light emitting layer to avoid affecting the light emitting layer.

Material of the spacers 34 may be the same as material of the light shielding layer 360. Moreover, the shapes and the size of the spacers 34 are not limited by the present disclosure.

In addition, the display panel may further include other conventional film layers which are not shown in figures. For example, a buffer layer may be formed between the thin film transistor layer 31 and the substrate 30. A planarization layer may be formed between the thin film transistor layer 31 and the pixel defining layer 32. A polarizer may be disposed on the color film layer 36.

The present disclosure further provides a manufacturing method for an organic light emitting diode (OLED) display panel, including the following steps:

In Step S10, a substrate is provided, and a thin film transistor layer and a pixel defining layer are formed on the substrate, wherein the pixel defining layer defines pixel regions distributed in an array.

The thin film transistor layer includes a gate, a gate insulating layer, an interlayer insulating layer, a source, a drain, and the like, and may further include other conventional film layers.

In Step S20, spacers are formed on the pixel defining layer, and then pixel units are formed in the pixel regions.

Material of the spacers is light shielding material. The spacers are disposed around at least one of the pixel regions, extend toward the adjacent pixel regions and terminate at edges of the pixel regions. The pixel units include an anode layer, a light emitting layer, and a cathode layer.

In Step S30, a thin film encapsulation layer is formed on the pixel units, and then a color film layer is formed on the thin film encapsulation layer, wherein the color film layer includes a plurality of color filter layers, each of which corresponds to one of the pixel units, and a light shielding layer disposed at each of intervals between the color filter layers;

Step S30 of forming the color film layer on the thin film encapsulation layer includes:

Step S301 of firstly forming a light shielding film on the thin film encapsulation layer, and patterning the light shielding film to form the light shielding layer corresponding to each of the intervals between any two of the adjacent pixel units; and

Step S302 of forming the color filter layers on the thin film encapsulation layer at positions corresponding to the pixel units.

Ink jet printing (IJP) technology is used for depositing the color filter layers, thereby reducing damage to the OLED structure in the manufacturing process.

Alternatively, the step S30 of forming the color film layer on the thin film encapsulation layer includes:

Step S301 of forming color filter films on the film encapsulation layer, and then patterning the color filter films to form the color filter layers, each of which corresponds to one of the pixel units; and

Step S302 of forming a light shielding film on the color filter layers, and then patterning the light shielding film to form the light shielding layer at each of the intervals between any two of the adjacent color filter layers, wherein the light shielding layer extends to edges of the color filter layers.

This method causes the light shielding layer to extend to the edges of the color filter layers, thereby enhancing the light absorbing effect of the light shielding layer, thereby improving the contrast of the display panel.

In the manufacturing method for the OLED display panel provided by the present disclosure, by disposing the color filter layers corresponding to the colors of the pixel units above the pixel units, and by locating a light shielding layer at each of intervals between the color filter layers, the manufacturing process orders of the color filter layers and the light shielding layer are used to improve the contrast of the display panel. In addition, the spacers are designed to have the functions for both supporting and light shielding in order to further improve the contrast of the display panel. The specific details are referred to the structural embodiment of the abovementioned display panel, and are not described herein.

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is disposed in the claims.

What is claimed is:

1. An organic light emitting diode (OLED) display panel, comprising:
a substrate;
a thin film transistor layer formed on the substrate;
a pixel defining layer formed on the thin film transistor layer, and defining pixel regions;
a plurality of spacers formed on the pixel defining layer;
a plurality of pixel units formed in the pixel regions and arranged in an array;
a thin film encapsulation layer formed on the pixel units; and
a color film layer formed on the film encapsulation layer, wherein the color film layer includes a plurality of color filter layers, each of which corresponds to one of the pixel units, and a light shielding layer disposed at each of intervals between the color filter layers, and extending to edges of the color filter layers;
wherein material of the spacers is light shielding material, and the spacers extend toward the pixel regions.

2. The OLED display panel, as claimed in claim 1, wherein the light shielding layer is a black matrix.

3. The OLED display panel as claimed in claim 1, wherein the plurality of spacers are disposed around at least one of the pixel regions and extend toward the adjacent pixel regions to edges of the pixel regions.

4. The OLED display panel as claimed in claim 1, wherein
a surface of the pixel defining layer is provided with recesses, and each of the recesses extends from an edge of one of the pixel regions to an edge of an adjacent one of the pixel regions, wherein each of the spacers is formed within one of the recesses.

5. The OLED display panel as claimed in claim 1, wherein material of the light shielding layer is same as the material of the spacers.

6. The OLED display panel according to claim 1, wherein at least a portion of a side of the pixel defining layer away from the thin film transistor layer is made of light shielding material.

7. A manufacturing method for an organic light emitting diode (OLED) display panel, comprising steps of:
Step S10 of providing a substrate, and forming a thin film transistor layer and a pixel defining layer on the substrate, wherein the pixel defining layer defines pixel regions distributed in an array;
Step S20 of forming spacers on the pixel defining layer, and then forming pixel units in one of the pixel regions; and
Step S30 of forming a thin film encapsulation layer on the pixel units, and then forming a color film layer on the thin film encapsulation layer, wherein the color film layer includes a plurality of color filter layers, each of which corresponds to one of the pixel units, and a light shielding layer disposed at each of intervals between the color filter layers;
wherein material of the spacers is light shielding material, and the spacers extend toward the pixel regions.

8. The manufacturing method as claimed in claim 7, wherein the plurality of spacers are disposed around at least one of the pixel regions and extend toward the adjacent pixel regions to edges of the pixel regions.

9. The manufacturing method as claimed in claim 7, wherein the step S30 of forming the color film layer on the thin film encapsulation layer includes:
Step S301 of firstly forming a light shielding film on the thin film encapsulation layer, and patterning the light shielding film to form the light shielding layer corresponding to each of the intervals between any two of the adjacent pixel units; and
Step S302 of forming the color filter layers on the thin film encapsulation layer at positions corresponding to the pixel units.

10. The manufacturing method as claimed in claim 7, wherein the step S30 of forming the color film layer on the thin film encapsulation layer includes:
Step S301 of firstly forming color filter films on the film encapsulation layer, and patterning the color filter films to form the color filter layers, each of which corresponds to one of the pixel units; and
Step S302 of forming a light shielding film on the color filter layers, and patterning the light shielding film to form the light shielding layer at each of the intervals between any two of the adjacent color filter layers, wherein the light shielding layer extends to edges of the color filter layers.

11. An organic light emitting diode (OLED) display panel, comprising:
a substrate;
a thin film transistor layer formed on the substrate;
a pixel defining layer formed on the thin film transistor layer, and defining pixel regions;
a plurality of spacers formed on the pixel defining layer;
a plurality of pixel units formed in one of the pixel regions and arranged in an array;
a thin film encapsulation layer formed on the pixel units; and
a color film layer formed on the film encapsulation layer, wherein the color film layer includes: a plurality of color filter layers, each of which corresponds to one of the pixel units, and a light shielding layer disposed at each of intervals between the color filter layers;
wherein material of the spacers is light shielding material, and each of the spacers extends toward the adjacent pixel regions.

12. The OLED display panel as claimed in claim 11, wherein the light shielding layer is a black matrix.

13. The OLED display panel as claimed in claim 11, wherein the plurality of spacers are disposed around at least one of the pixel regions and extend toward the adjacent pixel regions to edges of the pixel regions.

14. The OLED display panel as claimed in claim 11, wherein
a surface of the pixel defining layer is provided with recesses, and each of the recesses extends from an edge of one of the pixel regions toward an edge of an adjacent one of the pixel regions, wherein each of the spacers is formed within one of the recesses.

15. The OLED display panel as claimed in claim 11, wherein material of the light shielding layer is same as the material of the spacers.

16. The OLED display panel according to claim 11, wherein at least a portion of a side of the pixel defining layer away from the thin film transistor layer is made of light shielding material.
